(19) United States
(12) Patent Application Publication
(10) Pub. No.: US 2024/0317161 A1
(43) Pub. Date: Sep. 26, 2024

(54) DISTRIBUTED AUTOMOTIVE ELECTRONIC CONTROL UNITS WITH WIRED CONTROL CIRCUITRY

(71) Applicant: FORD GLOBAL TECHNOLOGIES, LLC, Dearborn, MI (US)

(72) Inventors: Kevin Vazquez, Commerce Township, MI (US); James Michael Weinfurther, Farmington, MI (US)

(21) Appl. No.: 18/189,695

(22) Filed: Mar. 24, 2023

(51) Int. Cl. B60R 16/023; G01R 31/00

(52) U.S. Cl. CPC B60R 16/0232; B60R 16/0238; G01R 31/007

(57) ABSTRACT

An automotive electronic control unit, responsive to indication of loss of communication with other automotive electronic control units, changes a voltage level on wiring interconnecting the automotive electronic control units such that the other of the automotive electronic control units reduce or preclude power flow to corresponding electrically powered components electrically connected with the other of the automotive electronic control units.

### TECHNICAL FIELD

This disclosure relates to automotive electrical systems.

### BACKGROUND

A vehicle may include various systems and subsystems each responsible for different functionality, such as braking, door locks, window movement, propulsion, etc. Electrical power is often used to activate and control these systems.

### SUMMARY

An automotive electrical system includes a plurality of electronic control units electrically connected via wiring. At least one of the electronic control units, responsive to indication of loss of communication with other of the electronic control units, changes a voltage level on the wiring such that the other of the electronic control units reduce or preclude power flow to corresponding electrically powered components electrically connected with the other of the electronic control units.

The at least one of the electronic control units may, responsive to indication of vehicle deactivation, change the voltage level such that the other of the electronic control units reduce or preclude power flow to the corresponding electrically powered components. The indication of vehicle deactivation may be a signal resulting from a button push. The indication of loss of communication may be a signal from a timer indicating at least a predefined period of time has passed since last receiving a message from the other of the electronic control units. The message may be a CAN message, a LIN message, an Ethernet message, or a FlexRay message. The at least one of the electronic control units may include circuitry electrically connected with the wiring and a microprocessor that generates output for the circuitry that causes the change. The at least one of the electronic control units may include a second microprocessor that generates an output for the circuitry that causes the change. The circuitry may be further electrically connected with a battery. The at least one of the electronic control units may, responsive to the indication, reduce or preclude power flow to a corresponding electrically powered component electrically connected with the at least one of the electronic control units.

A method includes, responsive to indication of loss of communication with electronic control units, changing a voltage level on wiring electrically connecting the electronic control units such that the electronic control units reduce or preclude power flow to corresponding electrically powered components electrically connected with the electronic control units.

The method may further include, responsive to indication of deactivation of a vehicle, changing the voltage level such that the electronic control units reduce or preclude power flow to the corresponding electrically powered components. The method may further include, responsive to passage of at least a predetermined period of time during which no messages are received from the electronic control units, generating the indication. The method may further include, responsive to the indication, reducing or precluding power flow to a corresponding electrically powered component.

A vehicle includes a plurality of electrically powered components and a plurality of electronic control units electrically connected via wiring. Each of the electronic control units provides power to at least one of the electrically powered components. At least one of the electronic control units includes circuitry electrically connected with the wiring and, responsive to indication of deactivation of the vehicle, generates output for the wiring that causes a voltage on the wiring to change such that the other of the electronic control units reduce or preclude power flow to the electrically powered components electrically connected therewith.

The indication of deactivation may be a signal resulting from a button push. The at least one of the electronic control units may further include a microprocessors that, responsive to indication of loss of communication with the other of the electronic control units, generates output for the circuitry that causes the voltage to change such that the other of the electronic control units reduce or preclude power flow to the electrically powered components electrically connected therewith. The at least one of the electronic control units may further include a second microprocessor that, responsive to the indication of loss of communication, generates output for the circuitry that causes the voltage to change such that the other of the electronic control units reduce or preclude power flow to the electrically powered components electrically connected therewith. The indication of loss of communication may be a signal from a timer indicating at least a predefined period of time has passed since last receiving a message from the other of the electronic control units. The message may be a CAN message, a LIN message, an Ethernet message, or a FlexRay message. The at least one electronic control unit may further, responsive to the indication, reduce or preclude power flow to the at least one of the electrically powered components electrically connected therewith.

### BRIEF DESCRIPTION OF THE DRAWINGS

FIG. 1 is a schematic diagram of a vehicle.

FIG. 2 is a schematic diagram of some of the electronic control units of FIG. 1.

FIGS. 3 and 4 are flow charts of algorithms for controlling operation of the electronic control units of FIG. 1.

### DETAILED DESCRIPTION

Embodiments are described herein. It is to be understood, however, that the disclosed embodiments are merely examples and other embodiments may take various and alternative forms. The figures are not necessarily to scale. Some features could be exaggerated or minimized to show details of particular components. Therefore, specific structural and functional details disclosed herein are not to be interpreted as limiting, but merely as a representative basis for teaching one skilled in the art.

Various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

An electronic control unit (ECU), in some examples, is a computer that controls and manages electronic systems in a vehicle or other complex machinery. Within the context of a vehicle, it can be responsible for monitoring and controlling an engine, transmission, brakes, climate control system, etc.

The ECU may receive input from various sensors throughout the vehicle, such as oxygen sensors, throttle position sensors, position sensors, and temperature sensors, and use that information to make real-time decisions about how the vehicle should operate. Some ECUs can adjust fuel injection, ignition timing, and other variables for performance, efficiency, and emissions reasons. Other ECUs can adjust power flow to electrically powered components, such as window motors, electrically powered door locks, brake actuators, etc.

Elements of an ECU can vary depending on the application and complexity of the system. ECUs, however, typically include at least one microprocessor, input/output (I/O) ports, memory, analog-to-digital converters (ADCs), a clock generator, a source of power, and a communication interface. The at least one microprocessor is responsible for executing software instructions that control the various systems corresponding thereto. The I/O ports connect the ECU to sensors and actuators that it controls: The I/O ports allow the ECU to receive input signals from sensors and send output signals to actuators. The memory may include read-only memory (ROM) and random-access memory (RAM). The ROM stores the firmware and operating system of the ECU, while the RAM is used to store data and temporary variables during operation. The ADCs are used to convert analog signals from sensors into digital signals that can be processed by the ECU. The clock generator generates clock signals that synchronize the operation of the at least one microprocessor and other components of the ECU. The source of power provides a stable and reliable power supply for the ECU. The communication interface, Controller Area Network (CAN), Local Interconnect Network (LIN), Ethernet, FlexRay, etc., permits the ECU to communicate with other ECUs or other systems.

Distributed electronic control units (ECUs) may allow for efficient and effective control of various vehicle systems. In some arrangements, a single ECU may have been used to manage all systems. Loss of that single ECU, however, could have created issues. The use of multiple or distributed ECUs permits redundant functionality.

Distributed ECUs can be a type of networked computing system that communicates with other systems to facilitate vehicle performance. These systems are connected to the ECUs, which communicate through various network protocols as suggested above.

The use of distributed ECUs may affect efficiency. With distributed ECUs, different systems within the vehicle can communicate with each other, and operate under a wide range of conditions, including different speeds, terrains, and weather conditions. The distributed system can then adjust the performance of the different systems for reasons related to fuel consumption, emissions, and other factors.

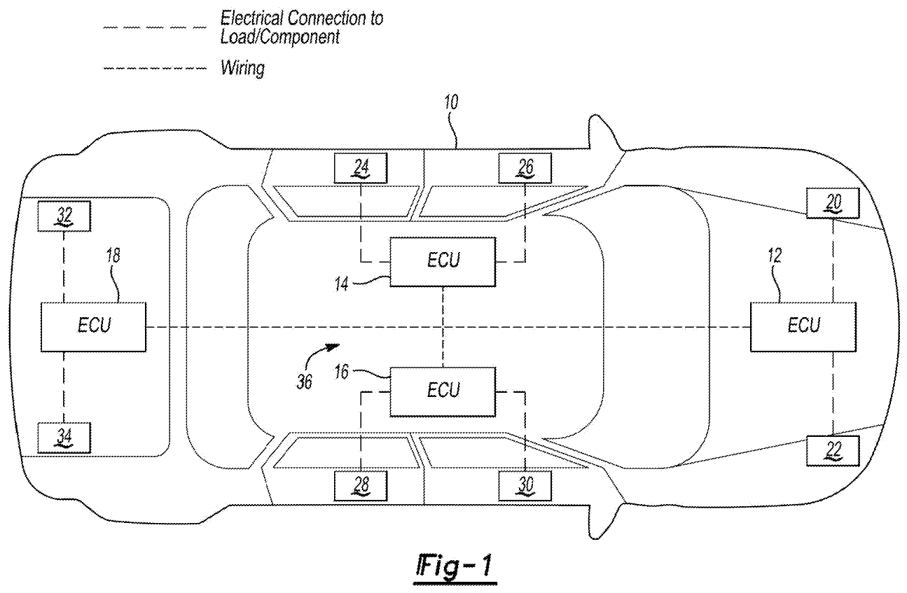

Referring to FIG. 1, an automotive vehicle 10 includes a plurality of ECUs 12, 14, 16, 18 and a plurality of electrically powered components 20, 22, 24, 26, 28, 30, 34, 34. As suggested above, the ECUs 12, 14, 16, 18 are configured as known in the art to communicate via a communication protocol, such as CAN, LIN, etc. The ECUs 12, 14, 16, 18, however, are also connected via a hard-wired circuit 36 (e.g., metal wiring), which is discussed more below.

Moreover, each of the electrically powered components 20, 22, 24, 26, 28, 30, 34, 34 is respectively electrically connected to a particular one of the ECUs 12, 14, 16, 18. The ECU 12 is in communication with/exerts control over the electrically powered components 20, 22. The ECU 14 is in communication with/exerts control over the electrically powered components 24, 26. The ECU 16 is in communication with/exerts control over the electrically powered components 28, 30. The ECU 18 is in communication with/exerts control over the electrically powered components 32, 34. That is, each of the ECUs 12, 14, 16, 18 is, among other things, arranged to control power flow (e.g. reduce power flow, increase power flow, prevent power flow, etc.) to corresponding ones of the electrically powered components 20, 22, 24, 26, 28, 30, 34, 34.

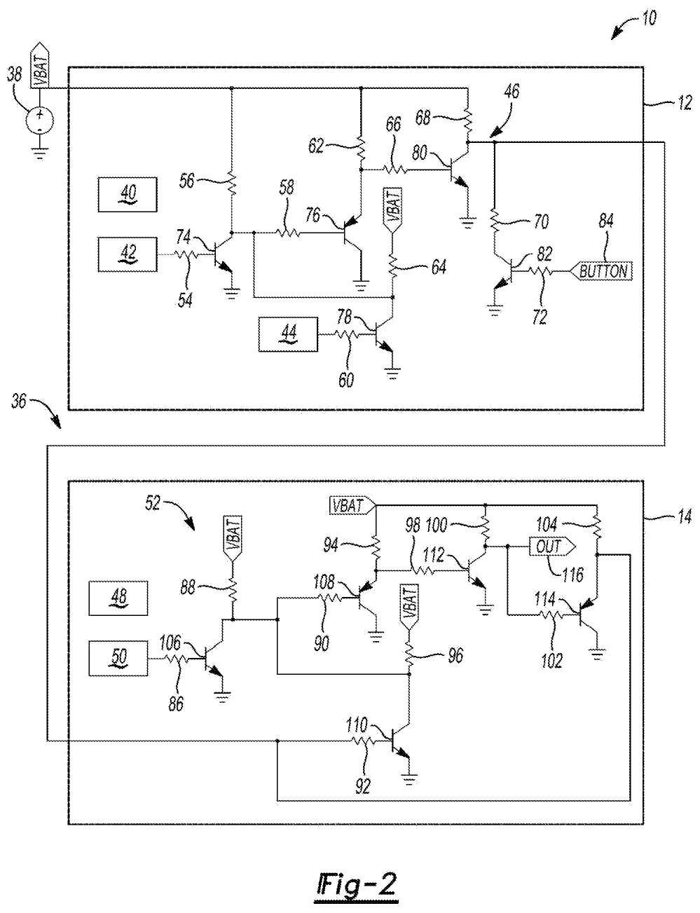

Referring to FIG. 2, the vehicle 10 further includes a battery 38. The ECU 12 includes, among other things, microprocessors 40, 42, 44 and circuitry 46. The ECU 14 includes, among other things, microprocessors 48, 50 and circuitry 52. The ECUs 16, 18 are constructed similarly to the ECU 14.

The circuitry 46 is electrically connected between the wiring 36 and battery 38. The circuitry 46, in this example, includes resistors 54, 56, 58, 60, 62, 64, 66, 68, 70, 72 and transistors 74, 76, 78, 80 82. The transistors 74, 78, 80, 82 are negative-positive-negative (npn) transistors. The transistor 76 is a positive-negative-positive (pnp) transistor. The resistor 54 is connected between the microprocessor 42 and a base of the transistor 74. The resistors 56, 62, 68 share a node with the battery 38. The resistor 56 is connected between the battery 38 and a collector of the transistor 74. The transistor 74 is connected between the resistor 56 and ground (e.g., chassis). The resistor 58 is connected between a collector of the transistor 74 and a base of the transistor 76. The resistor 60 is connected between the microprocessor 44 and a base of the transistor 78. The resistor 64 is connected between the battery 38 and a collector of the transistor 78. The resistor 62 is connected between the battery 38 and an emitter of the transistor 76. The transistor 76 is connected between the resistor 62 and ground. The resistor 66 is connected between an emitter of the transistor 76 and base of the transistor 80. The resistor 68 is connected between the battery 38 and a collector of the transistor 80. The transistor 80 is connected between the resistor 68 and ground. The resistor 70 is connected between the wiring 36 and a collector of the transistor 82. The transistor 82 is connected between the resistor 70 and ground. The resistor 72 is connected between the transistor 82 and a start/stop button 84 of the vehicle 10, which is not part of the ECU 12. The start/stop button 84, when pressed, generates a signal indicating the vehicle 10 is being activated/deactivated. The resistors 68, 70 and a collector of the transistor 80 share a node with the wiring 36.

The circuitry 52 is electrically connected with the wiring 36. The circuitry 52, in this example, includes resistors 86, 88, 90, 92, 94, 96, 98, 100, 102, 104 and transistors 106, 108, 110, 112, 114. The transistors 106, 110, 112 are npn transistors. The transistors 108, 114 are pnp transistors. The resistor 86 is connected between the microprocessor 50 and base of the transistor 74. The resistor 88 is connected between the battery 38 and a collector of the transistor 106. The transistor 106 is connected between the resistor 88 and ground. The resistors 88, 90, 96 and a collector of the transistor 106 share a node. The resistor 92 is connected between the wiring 36 and a base of the transistor 110. The resistor 96 is connected between the battery 38 and a collector of the transistor 110. The transistor 110 is connected between the resistor 96 and ground. The transistor 108 is connected between the resistor 94 and ground. The resistors 94, 100, 104 share a node with the battery 38. The resistors 94, 98 share a node with an emitter of the transistor 108. The transistor 112 is connected between the resistor 100 and ground. The resistors 100, 102 and an output 116 of the electronic control unit 14 share a node with a collector of the transistor 112. The resistors 92, 104 share a node with an emitter of the transistor 114. The transistor 114 is connected between the wiring 36 and ground.

Loss of standard communication between the electronic control units 12, 14, 16, 18 could result from a fault associated with the electronic control units 12, 14, 16, 18 or a fault elsewhere in the vehicle 10. The I/O port of the electronic control unit 12, for example, could become disabled, etc. The electronic control units 12, 14, 16, 18 may have difficulty coordinating their activities without such communication. The wiring 36 is thus used to communicate electronic control unit state among the electronic control units 12, 14, 16, 18 to maintain some level of coordination.

The circuitries 46, 52, in concert with the battery 38, are arranged such that the voltage on the wiring 36 is normally low (e.g., 1 V). That is, during periods of proper electronic control unit operation and communication, the voltage on the wiring 36 is low. Such is interpreted by the microprocessors 40, 48 (and corresponding microprocessors of the electronic control units 16, 18) as an indication that all is in proper order. During periods of improper electronic control unit operation or communication however, the voltage on the wiring 36 is high as discussed in more detail below.

In this example, the microprocessor 40 implements a so called watch dog timer to monitor the amount of time that passes between receiving messages (e.g., CAN messages, LIN messages, etc.) from each of the electronic control units 14, 16, 18. If a predetermined period of time passes (e.g., 1 second, 20 seconds, etc.) without the electronic control unit 12 receiving a message from the electronic control unit 14, the microprocessor 40 generates output for the microprocessors 42, 44 indicating the electronic control unit 12 has lost communication with the electronic control unit 14. The same would hold true for the electronic control units 16, 18. Responsive to the output indicating the electronic control unit 12 has lost communication with the electronic control unit 14 (or the electronic control units 16, 18), the microprocessors 42, 44 each generate output for the circuitry 46 that force the voltage on the wiring 36 to go high (e.g., 5V). The microprocessor 44 is a backup to the microprocessor 42. That is, only one of the microprocessors 42, 44 needs to generate output for the circuitry 46 in order to force the voltage on the wiring 36 to go high.

The circuitry 46, as mentioned above, is also connected with the start/stop button 84 such that if, for example, a driver were to press the start/stop button 84 to deactivate the vehicle 10 upon completion of a drive cycle, the resulting signal therefrom would force the voltage on the wiring 36 to go high. This may be useful, for example, in circumstances in which the electronic control unit 12 is otherwise not able to communicate with the electronic control units 14, 16, 18 to alert them as to the vehicle 10 being deactivated.

The microprocessor 48 (and corresponding microprocessors of the electronic control units 12, 16, 18) interpret the high state on the wiring 36 as indication that standard communication has been lost with at least one of the other electronic control units 12, 14, 16, 18. In response, the microprocessor 48 (and corresponding microprocessors of the electronic control units 12, 16, 18) generates commands to reduce or preclude power flow to the electrically powered components electrically connected therewith. Whether a particular one of the electronic control units 12, 14, 16, 18 reduces or precludes power flow to the electrically powered components electrically connected therewith may depend on the electrically powered components electrically connected therewith. If an electrically powered component is an entertainment system, power flow may be precluded. If an electrically powered component is an electrically powered air conditioner, power flow may be reduced.

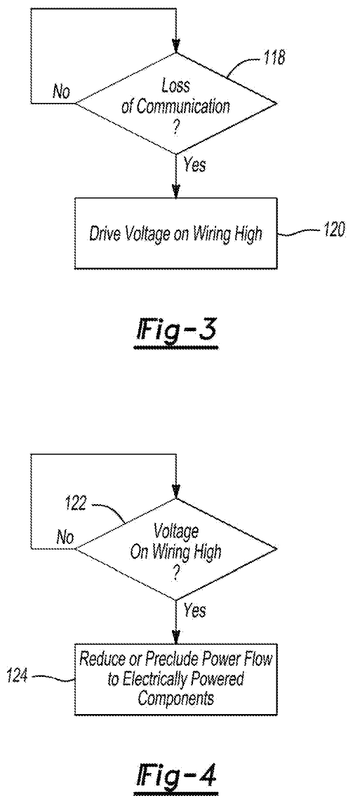

Referring to FIG. 3, at operation 118, it is determined whether loss of communication with other electronic control units has occurred. If no, the algorithm returns to operation 118. If yes, the voltage on the wiring connecting the electronic control units is driven high at operation 120.

Referring to FIG. 4, at operation 122, it is determined whether the voltage is high on the wiring connecting the electronic control units. If no, the algorithm returns to operation 122. If yes, the power flow to the corresponding electronic control units is reduced or precluded.

The algorithms, methods, or processes disclosed herein can be deliverable to or implemented by a computer, controller, or processing device, which can include any dedicated electronic control unit or programmable electronic control unit. Similarly, the algorithms, methods, or processes can be stored as data and instructions executable by a computer or controller in many forms including, but not limited to, information permanently stored on non-writable storage media such as read only memory devices and information alterably stored on writeable storage media such as compact discs, random access memory devices, or other magnetic and optical media. The algorithms, methods, or processes can also be implemented in software executable objects. Alternatively, the algorithms, methods, or processes can be embodied in whole or in part using suitable hardware components, such as application specific integrated circuits, field-programmable gate arrays, state machines, or other hardware components or devices, or a combination of firmware, hardware, and software components.

While exemplary embodiments are described above, it is not intended that these embodiments describe all possible forms encompassed by the claims. Circuit topologies other than those described with reference to FIG. 2 may, of course, be used. Moreover, a high voltage state for the wiring interconnecting the electronic control units may be used to indicate normal operating conditions, and a low voltage state may be used to indicate loss of standard communication as design requirements dictate.

The words used in the specification are words of description rather than limitation, and it is understood that various changes may be made without departing from the spirit and scope of these disclosed materials. The terms “controller” and “controllers,” for example, can be used interchangeably herein.

As previously described, the features of various embodiments may be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics may be compromised to achieve desired overall system attributes, which depend on the specific application and implementation. These attributes may include, but are not limited to strength, durability, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and may be desirable for particular applications.

What is claimed is:

1. An automotive electrical system comprising:
a plurality of electronic control units electrically connected via wiring, at least one of the electronic control units configured to, responsive to indication of loss of communication with other of the electronic control units, change a voltage level on the wiring such that the other of the electronic control units reduce or preclude power flow to corresponding electrically powered components electrically connected with the other of the electronic control units.

2. The automotive electrical system of claim 1, wherein the at least one of the electronic control units is further configured to, responsive to indication of vehicle deactivation, change the voltage level such that the other of the electronic control units reduce or preclude power flow to the corresponding electrically powered components.

3. The automotive electrical system of claim 2, wherein the indication of vehicle deactivation is a signal resulting from a button push.

4. The automotive electrical system of claim 1, wherein the indication of loss of communication is a signal from a timer indicating at least a predefined period of time has passed since last receiving a message from the other of the electronic control units.

5. The automotive electrical system of claim 4, wherein the message is a CAN message, a LIN message, an Ethernet message, or a FlexRay message.

6. The automotive electrical system of claim 4, wherein the at least one of the electronic control units includes circuitry electrically connected with the wiring and a microprocessor programmed to generate output for the circuitry that causes the change.

7. The automotive electrical system of 6, wherein the at least one of the electronic control units includes a second microprocessor programmed to generate an output for the circuitry that causes the change.

8. The automotive electrical system of claim 6, wherein the circuitry is further electrically connected with a battery.

9. The automotive power electrical system of claim 1, wherein the at least one of the electronic control units is further configured to, responsive to the indication, reduce or preclude power flow to a corresponding electrically powered component electrically connected with the at least one of the electronic control units.

10. A method comprising:
responsive to indication of loss of communication with electronic control units, changing a voltage level on wiring electrically connecting the electronic control units such that the electronic control units reduce or preclude power flow to corresponding electrically powered components electrically connected with the electronic control units.

11. The method of claim 10 further comprising, responsive to indication of deactivation of a vehicle, changing the voltage level such that the electronic control units reduce or preclude power flow to the corresponding electrically powered components.

12. The method of claim 10 further comprising, responsive to passage of at least a predetermined period of time during which no messages are received from the electronic control units, generating the indication.

13. The method of claim 10 further comprising, responsive to the indication, reducing or precluding power flow to a corresponding electrically powered component.

14. A vehicle comprising:
a plurality of electrically powered components; and
a plurality of electronic control units electrically connected via wiring, each of the electronic control units configured to provide power to at least one of the electrically powered components, and at least one of the electronic control units including circuitry electrically connected with the wiring and configured to, responsive to indication of deactivation of the vehicle, generate output for the wiring that causes a voltage on the wiring to change such that the other of the electronic control units reduce or preclude power flow to the electrically powered components electrically connected therewith.

15. The vehicle of claim 14, wherein the indication of deactivation is a signal resulting from a button push.

16. The vehicle of claim 14, wherein the at least one of the electronic control units further includes a microprocessors programmed to, responsive to indication of loss of communication with the other of the electronic control units, generate output for the circuitry that causes the voltage to change such that the other of the electronic control units reduce or preclude power flow to the electrically powered components electrically connected therewith.

17. The vehicle of claim 16, wherein the at least one of the electronic control units further includes a second microprocessor programmed to, responsive to the indication of loss of communication, generate output for the circuitry that causes the voltage to change such that the other of the electronic control units reduce or preclude power flow to the electrically powered components electrically connected therewith.

18. The vehicle of claim 16, wherein the indication of loss of communication is a signal from a timer indicating at least a predefined period of time has passed since last receiving a message from the other of the electronic control units.

19. The vehicle of claim 18, wherein the message is a CAN message, a LIN message, an Ethernet message, or a FlexRay message.

20. The vehicle of claim 14, wherein the at least one electronic control unit is further configured to, responsive to the indication, reduce or preclude power flow to the at least one of the electrically powered components electrically connected therewith.
